(19) United States
(12) Patent Application Publication
(10) Pub. No.: US 2025/0089182 A1
(43) Pub. Date: Mar. 13, 2025

(54) PAINTING PROTECTOR AND CUBICLE USING THE SAME

(71) Applicant: TMEIC Corporation, Tokyo (JP)

(72) Inventor: Nobuhiro TAKAHASHI, Tokyo (JP)

(73) Assignee: TMEIC Corporation, Tokyo (JP)

(21) Appl. No.: 18/728,227

(22) PCT Filed: Dec. 20, 2022
(86) PCT No.: PCT/JP2022/046855

§ 371 Date: Jul. 11, 2024

(51) Int. Cl. H05K 5/02; H05K 5/04

(52) U.S. Cl. CPC H05K 5/02; H05K 5/04

(57) ABSTRACT

The present cubicle is an outdoor installation type cubicle, and comprises a surface component formed using a painted metal plate and exposed to an outside of the cubicle and a painting protector attached to an edge of the surface component. The painting protector comprises a front cover, a back cover, and an edge cover. The front cover comes into contact with a front side of the edge when the painting protector is attached to the edge. The back cover comes into contact with a back side of the edge when the painting protector is attached to the edge. The edge cover connects the front cover and the back cover and covers a tip of the edge when the painting protector is attached to the edge. The front cover, the back cover, and the edge cover are integrally molded of ASA resin.

### TECHNICAL FIELD

The present disclosure relates to a painting protector attached to an edge of a painted metal plate, and an outdoor installation type cubicle using the painting protector.

### BACKGROUND ART

A cubicle is made by processing a plurality of metal plates. The metal plate is painted to prevent corrosion due to rust. However, the painting of the cubicle installed outdoors is easily deteriorated under the influence of ultraviolet rays, ozone, dirt, rain, snow, and the like. In particular, in a salt-damaged area, the salt attached to the cubicle promotes the deterioration of the painting.

Patent Document 1 discloses an example of a prior art for protecting a cubicle from rust. According to the prior art disclosed in Patent Document 1, the entire cubicle is covered with a protective cover in order to block the influence of the external environment that causes corrosion of the cubicle. The protective cover used in this prior art is made by assembling divided panel plates made of synthetic resin.

However, a considerable cost is required to manufacture a protective cover of synthetic resin that can cover the entire cubicle. If the size of the cubicle were fixed, a mass production effect may be expected, but the size of the cubicle in the market varies. For operators who need to install a large number of cubicles outdoors, the use of protective covers as a means of protecting the cubicles from rust is difficult to adopt, at least from a cost perspective.

### PRIOR ART DOCUMENT

### Patent Document

[Patent Document 1] JP2005-16807A

### SUMMARY OF THE INVENTION

### Problems to be Solved by the Invention

The present disclosure has been made in view of the above problem. An object of the present disclosure is to provide a technique that contributes to suppressing the generation of rust due to deterioration of painting in a cubicle installed outdoors.

### Solution to Problem

The present disclosure provides a painting protector. The painting protector of the present disclosure is a member to be attached to an edge of a painted metal plate, and includes a front cover, a back cover, and an edge cover. The front cover is a part that comes into contact with a front side of the edge when the painting protector is attached to the edge of the metal plate. The back cover is a part that comes into contact with a back side of the edge when the painting protector is attached to the edge of the metal plate. The edge cover is a part that connects the front cover and the back cover and that covers a tip of the edge when the painting protector is attached to the edge of the metal plate. The front cover, the back cover, and the edge cover are integrally molded of ASA resin.

In the above-described painting protector, the front cover may be a flat plate that is in close contact with the front side of the edge of the metal plate. The back cover may be a curved plate that is curved or bent outward, and forms a gap between a tip of the back cover and the back side of the edge of the metal plate when the painting protector is attached to the edge of the metal plate. The inside of the edge cover may be filled with caulking material.

The present disclosure provides an outdoor installation type cubicle to which the painting protector is applied. The cubicle according to the present disclosure includes a surface component formed using a painted metal plate and exposed to the outside of the cubicle, and the above-described painting protector is attached to an edge of the surface component. The inside of the edge cover of the painting protector may be filled with caulking material.

The surface component may be a side panel. In this case, the painting protector may be attached to a side edge of the side panel. For example, the painting protector may be attached such that the front cover is in contact with an outer surface of the side edge of the side panel and the back cover is in contact with an inner surface of the side edge of the side panel. The front cover may be formed in a flat plate shape so as to be in close contact with the outer surface of the side edge of the side panel.

The surface component may be a door with at least a lower edge bent inward. In this case, the painting protector may be attached to the lower edge of the door. For example, the painting protector may be attached such that the front cover is in contact with an upper surface of the lower edge of the door and the back cover is in contact with a lower surface of the lower edge of the door. The front cover may be formed in a flat plate shape so as to be in close contact with the upper surface of the lower edge of the door.

The surface component may be an eave provided on an upper part of the door. In this case, the painting protector may be attached to a front edge of the eave. For example, the painting protector may be attached such that the front cover is in contact with an upper surface of the front edge of the eave and the back cover is in contact with a lower surface of the front edge of the eave. The front cover may be formed in a flat plate shape so as to be in close contact with an upper surface of the front edge of the eave.

### Effects of the Invention

The edge of the metal plate is a portion where the painting is most likely to deteriorate and rust is most likely to generate in the metal plate because the painting is unlikely to be applied. According to the painting protector of the present disclosure, the painting on the edge of the metal plate is protected by the front cover, the back cover, and the edge cover integrally molded of ASA resin having excellent weather resistance, and thus it is possible to suppress the generation of rust on the edge of the metal plate due to the deterioration of the painting. According to the cubicle of the present disclosure in which such a painting protector is attached to the edge of the surface member, it is possible to suppress the generation of rust due to the deterioration of the painting without high cost.

### BRIEF DESCRIPTION OF DRAWINGS

FIG. 1 is a cross-sectional view of an edge of a painted metal plate.

FIG. 2 is a perspective view of a painting protector according to an embodiment of the present disclosure.

FIG. 3 is a cross-sectional view of the painting protector according to the embodiment of the present disclosure which is attached to the edge of the metal plate.

FIG. 4 is a perspective view of a cubicle according to the embodiment of the present disclosure.

FIG. 5 is a rear view of a door of the cubicle according to the embodiment of the present disclosure.

FIG. 6 is a cross-sectional view of a lower part of the door of the cubicle according to the embodiment of the present disclosure.

FIG. 7 is a cross-sectional view of an eave and an upper part of the door of the cubicle according to the embodiment of the present disclosure.

### DETAILED DESCRIPTION OF THE INVENTION

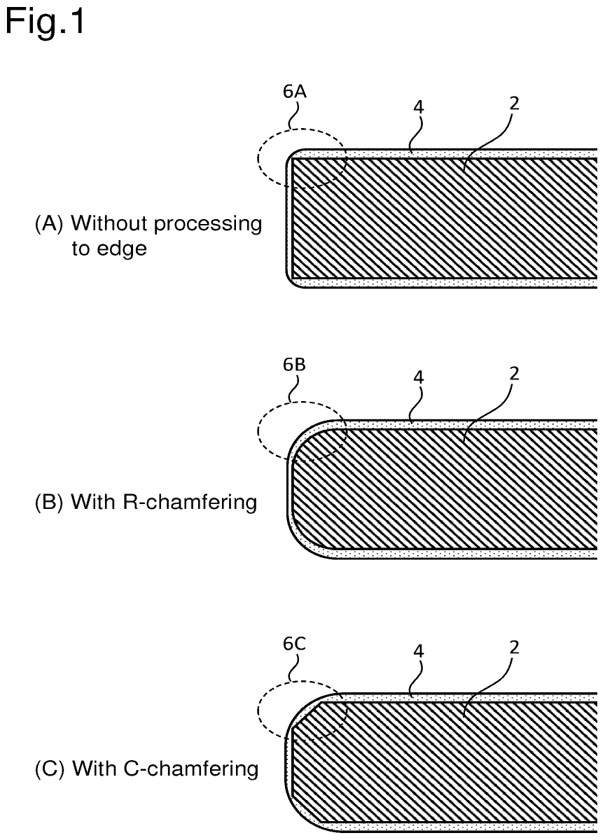

Typically, a metal plate used for a surface component of a cubicle is a steel material. Therefore, the surface of the metal plate is painted for the purpose of rust prevention and corrosion prevention. Ideally, the thickness of the painting film is uniform over the entire metal plate. However, as shown in the cross-sectional view (A) of FIG. 1, when the end of the metal plate 2 is left uncut and has an edge at a corner 6A, the thinness of painting film 4 at the corner 6A becomes a problem. According to a verification result, the thickness of the painting film on the corner 6A having an edge is only about 30% of the thickness of the painting film on a flat area.

As a method for improving the adhesion of painting material at the end of the metal plate, there are a method of performing R-chamfering on a corner 6B as shown in the sectional view (B) of FIG. 1 and a method of performing C-chamfering on a corner 6C as shown in the sectional view (C) of FIG. 1. By performing these processes, the film thickness of the painting film at the corner is improved to about 60% to 70% of the flat area. However, since the film thickness is still thinner than that of the flat area, even if these processes are performed, there still remains a possibility of rust due to deterioration of painting in harsh environments. Furthermore, many of the plate materials used for the cubicle have a plate thickness of 1.6 to 2.3 mm with respect to a length of just under 2 m. When such a plate material is processed by hand, it is difficult to uniformly maintain the finish of the end.

For the above reasons, the painting on the edge of the metal plate used for surface component of the cubicle is more likely to deteriorate than that on the flat area, and the edge from which the painting has peeled off is more likely to be corroded by rust. However, looking at this in reverse, if the painting on the edge of the metal plate can be protected, it can be said that the corrosion due to rust can be suppressed as the whole metal plate. A proposal based on such an idea is a painting protector according to an embodiment of the present disclosure.

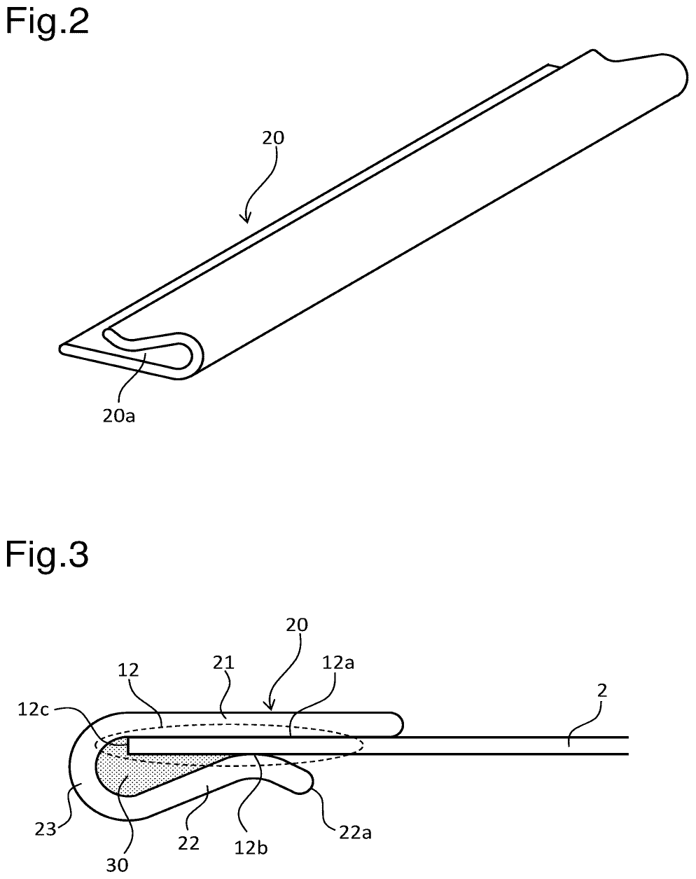

FIG. 2 is a perspective view of the painting protector 20 according to the present embodiment. The painting protector 20 is shaped like a plate that extends in one direction and is bent along its longitudinal direction. The painting protector 20 is a member to be attached to the edge of a painted metal plate. When the painting protector 20 is attached, the edge of the metal plate is inserted into a groove 20a of the painting protector 20. The length of the paint protector 20 is adapted to the length of the edge of the metal plate to be attached.

FIG. 3 is a cross-sectional view of the painting protector 20 according to the present embodiment which is attached to the edge 12 of the metal plate 2. The painting protector 20 includes a front cover 21, a back cover 22, and an edge cover 23 that connects the front cover 21 and the back cover 22. The front cover 21, the back cover 22, and the edge cover 23 are integrally molded, and have a uniform thickness from a tip of the front cover 21 to a tip of the back cover 22 through the edge cover 23.

The front cover 21 is a part that comes into contact with a front side 12a of the edge 12 when the painting protector 20 is attached to the edge 12 of the metal plate 2. The front cover 21 has a flat plate shape that is in close contact with the front side 12a of the edge 12. The back cover 22 is a part that comes into contact with a back side 12b of the edge 12 when the painting protector 20 is attached to the edge 12 of the metal plate 2. The back cover 22 has a curved plate shape that is curved or bent outward. When the painting protector 20 is attached to the edge 12, a gap is formed between a tip 22a of the back cover 22 and the back side 12b of the edge 12. The edge cover 23 is a part that covers a tip 12c of the edge 12 when the painting protector 20 is attached to the edge 12 of the metal plate 2.

A gap between the front cover 21 and the back cover 22 when the painting protector 20 is not attached to the edge 12 of the metal plate 2 is smaller than the thickness of the metal plate 2. Therefore, when the painting protector 20 is attached to the edge 12 of the metal plate 2, the gap between the front cover 21 and the back cover 22 is enlarged, and a pressing force due to elastic deformation acts on the edge 12 of the metal plate 2 from the front cover 21 and the back cover 22. The action of the pressing force prevents the painting protector 20 from being detached from the edge 12 of the metal plate 2.

The inside of the edge cover 23 is filled with caulking material 30. The caulking material 30 prevents rainwater from flowing into the edge cover 23 from openings at both ends of the painting protector 20. The caulking material 30 may be filled so as to fill the gap inside the edge cover 23 over the entire length of the painting protector 20, or may be filled only inside the edge cover 23 near the openings so as to close the openings at both ends of the painting protector 20.

The material of the painting protector 20 is acrylonitrile-styrene-acrylic acid ester (ASA) resin. The front cover 21, the back cover 22, and the edge cover 23 are formed by injection molding of ASA resin. The reason why ASA resin is used as the material of the painting protector 20 is that ASA resin has good weather resistance. For example, consider the case where the painting protector 20 is applied to a surface component of a cubicle. In the environment where an outdoor installation type cubicle is installed, there is an influence by ultraviolet rays, ozone, dirt, rain, snow, and the like, and in some regions, is also an influence by salt damage. Therefore, the painting protector 20 also needs to have weather resistance enough to withstand such an environment. As a result of repeated studies on materials that provide the painting protector 20 with necessary weather resistance, ASA resin was selected as the most suitable material. ASA resin has better weather resistance than ABS resin which is a general-purpose plastic. Therefore, the painting protector 20 made of ASA resin can maintain its performance even in an environment where the painting protector made from ABS resin cannot last long.

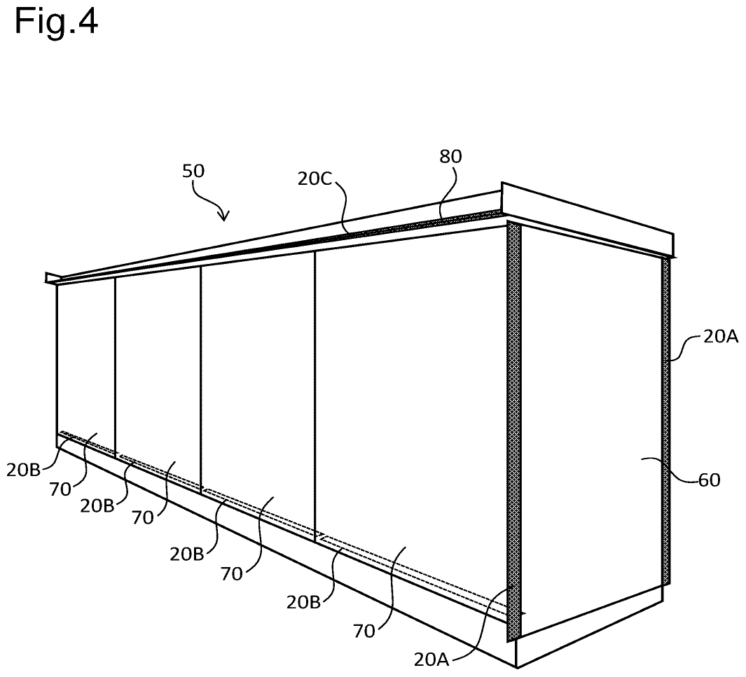

FIG. 4 is a perspective view of a cubicle 50 according to the present embodiment. The painting protector according to the present embodiment is applied to the cubicle 50. In the present disclosure, the cubicle means a housing that houses devices such as a power conversion device, a control panel, a communication device, and a signal. In the present disclosure, the device housed in the cubicle is not limited.

In the present embodiment, the paint protector is applied to a surface component formed using a painted metal plate exposed to the outside of the cubicle 50. For example, a side panel 60, a door 70, and an eave 80 provided on an upper part of the door 70 correspond to such surface components. A painting protector 20A is attached to the side panel 60, a painting protector 20B is attached to the door 70, and a painting protector 20C is attached to the eave 80. The painting protectors 20A, 20B, and 20C are included in the painting protector 20 shown in FIGS. 2 and 3.

As for the side panel 60, the painting protector 20A is attached to both side edges of the side panel 60. The painting protector 20A is attached such that the front cover is in contact with the outer surface of the side edge and the back cover is in contact with the inner surface of the side edge. The inside of the edge cover of the painting protector 20A is filled with caulking material.

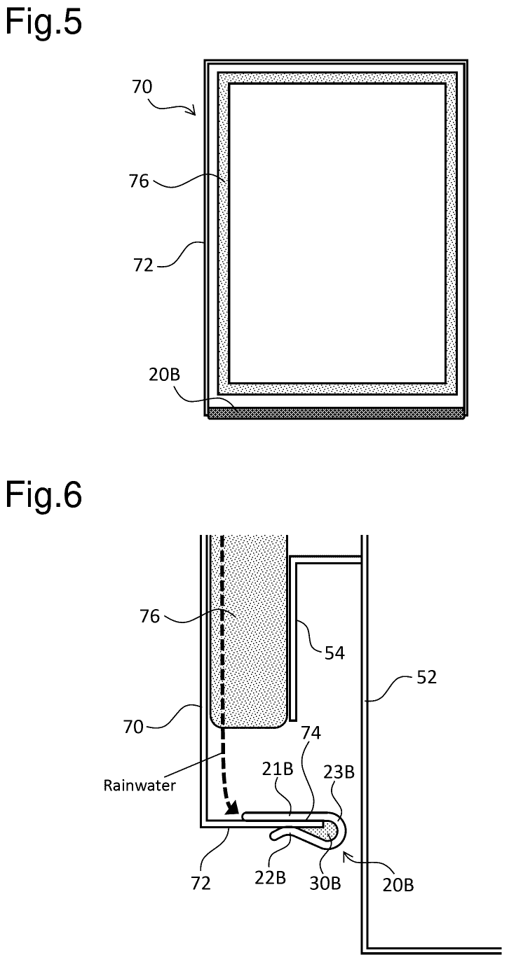

Next, the attachment of the painting protector 20B to the door 70 will be described. FIG. 5 is a rear view of the door 70, and FIG. 6 is a sectional view of a lower part of the door 70. The door 70 has an outer frame 72 bent inward, and a packing 76 is stuck to the inside of the outer frame 72. The packing 76 abuts on a pressing frame 54 provided on a frame 52 when the door 70 is closed, and seals the inside of the cubicle 50.

The painting protector 20B is attached to a lower edge 74 of the outer frame 72 of the door 70. The lower edge 74 of the outer frame 72 is a portion where rainwater flowing along the packing 76 is likely to stay and rust is particularly likely to be generated. Therefore, the painting protector 20B is attached to prevent the generation of rust. The painting protector 20B is attached such that a front cover 21B is in contact with an upper surface of the lower edge 74 and a back cover 22B is in contact with a lower surface of the lower edge 74. That is, in this attachment example, the upper surface of the lower edge 74 is the front side, and the lower surface of the lower edge 74 is the back side. The inside of an edge cover 23B of the painting protector 20B is filled with caulking material 30B.

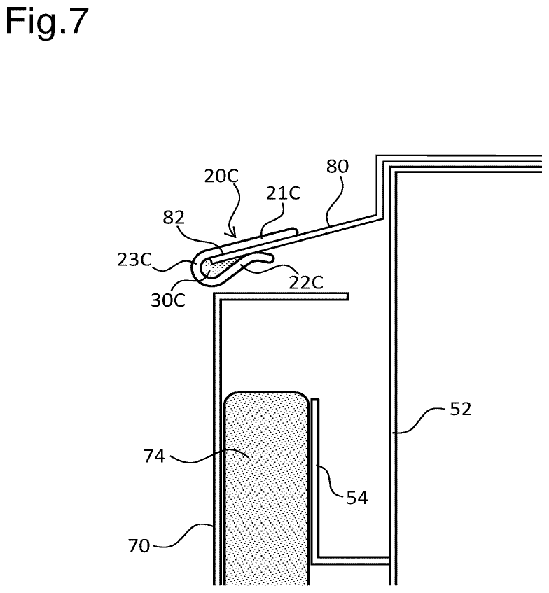

Next, the attachment of the painting protector 20C to the eave 80 will be described. FIG. 7 is a cross-sectional view of an upper part of the door 70. The eave 80 is provided to cover the upper part of the door 70 for the purpose of preventing rainwater from flowing into the inside of the door 70. The eave 80 is always exposed to rainwater in rainy weather, and rainwater flowing from the roof drips from a front edge 82 of the eave 80. Therefore, the front edge 82 of the eave 80 is a portion where rainwater is likely to adhere and rust is particularly likely to generate. Therefore, the painting protector 20C is attached to prevent the generation of rust. The painting protector 20C is attached such that a front cover 21C is in contact with an upper surface of the front edge 82 and a back cover 22C is in contact with a lower surface of the front edge 82. The inside of an edge cover 23C of the painting protector 20C is filled with caulking material 30C.

According to the cubicle 50 of the present embodiment, by applying the painting protectors 20A, 20B, and 20C to the surface components, it is possible to suppress the generation of rust due to the deterioration of the painting without requiring a high initial cost, and it is possible to reduce the maintenance cost of the cubicle 50. The painting protector according to the present embodiment is expected to contribute to the prevention of the corrosion of the metal plate also when applied to a cubicle installed in a place with a particularly bad surrounding environment among indoor installation type cubicles, for example, a cubicle for a chemical factory facility or a sewage facility.

### DESCRIPTION OF SYMBOLS

2 Metal plate
12 Edge
12a Front side of edge
12b Back side of edge
12c Tip of edge
20, 20A, 20B, 20C Painting protector
21, 21B, 21C Front cover
22, 22B, 22C Back cover
23, 23B, 23C Edge cover
30, 30B, 30C Caulking material
50 Cubicle
60 Side panel
70 Door
74 Lower edge of door
80 Eave
82 Front edge of eave

1. A painting protector attached to an edge of a painted metal plate, comprising:
a front cover that comes into contact with a front side of the edge when the painting protector is attached to the edge;
a back cover that comes into contact with a back side of the edge when the painting protector is attached to the edge; and
an edge cover connecting the front cover and the back cover that covers a tip of the edge when the painting protector is attached to the edge,
wherein the front cover, the back cover, and the edge cover are integrally molded of ASA resin,
the front cover is a flat plate that is in close contact with the front side of the edge, and
the back cover is a curved plate that is curved or bent outward, and forms a gap between a tip of the back cover and the back side of the edge when the painting protector is attached to the edge.

2. (canceled)

3. The painting protector according to claim 1, wherein
caulking material is filled inside the edge cover.

4. An outdoor cubicle, comprising:
a surface component formed using a painted metal plate and exposed to an outside of the outdoor cubicle; and
a painting protector attached to an edge of the surface component,
wherein the painting protector comprises:
a front cover that comes into contact with a front side of the edge when the painting protector is attached to the edge;
a back cover that comes into contact with a back side of the edge when the painting protector is attached to the edge; and
an edge cover connecting the front cover and the back cover that covers a tip of the edge when the painting protector is attached to the edge,
the front cover, the back cover, and the edge cover are integrally molded of ASA resin,
the surface component is an eave provided on an upper part of a door, and
the painting protector is attached to a front edge of the eave.

5-9. (canceled)

10. The outdoor cubicle according to claim 4, wherein
the painting protector is attached such that the front cover is in contact with an upper surface of the front edge and the back cover is in contact with a lower surface of the front edge, and
the front cover is formed in a flat plate shape so as to be in close contact with the upper surface.

11. The outdoor cubicle according to claim 4, wherein
caulking material is filled inside the edge cover.

12. The outdoor cubicle according to claim 10, wherein
caulking material is filled inside the edge cover.
